(19) United States
(12) Patent Application Publication
(10) Pub. No.: US 2006/0254496 A1
(43) Pub. Date: Nov. 16, 2006

(54) Phase transition method of organic based complex and its functional element

(75) Inventors: Shinya Koshihara, Tokyo (JP); Gunji Saito, Kyoto (JP); Hideki Yamochi, Kyoto (JP); Tadahiko Ishikawa, Tokyo (JP); Naoki Uchida, Nagano (JP); Soichi Fukaya, Niigate (JP); Akira Ota, Tokyo (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: JAPAN SCIENCE AND TECHNOLOGY AGENCY, SAITAMA (JP)

(21) Appl. No.: 10/546,240

(22) PCT Filed: Mar. 4, 2004
(86) PCT No.: PCT/JP04/02761

§ 371 Date: Aug. 22, 2005

(30) Foreign Application Priority Data
Sep. 8, 2003 (JP) 2003-315978

(51) Int. Cl. H01L 21/322; C30B 15/14

(52) U.S. Cl. 117/2; 117/3

(57) ABSTRACT

A method for performing a phase transition of an organic complex in which the phase transition can be performed with a high performance under specific conditions and a functional element using the same are provided. When EDO-TTF-based complex crystals are irradiated with photons as weak as about 1 to about 10 μJ per square centimeter, the EDO-TTF-based complex crystals undergo a phase transition to a metal phase (high temperature phase) and an insulator phase (low temperature phase), thereby changing the reflection spectrum and the electric conductivity. Thus, the operation is performed in a wavelength region of 1.5 to 0.8 μm with a high-sensitivity, at a high speed, and at room temperature.

### TECHNICAL FIELD

The present invention relates to a method for performing a phase transition of an organic complex and a functional element using the same, and in particular, to a method for performing a phase transition of an EDO-TTF-based complex and a functional element using the same.

### BACKGROUND ART

Although the above EDO-TTF-based complex crystals are not used, the following Patent Documents 1 to 5 disclose liquid crystal materials or devices serving as an optical switch or performing a phase transition.

[Patent Document 1] Japanese Unexamined Patent Application Publication No. 5-53088

[Patent Document 2] Japanese Unexamined Patent Application Publication No. 5-262698

[Patent Document 3] Japanese Unexamined Patent Application Publication No. 6-116246

[Patent Document 4] Japanese Unexamined Patent Application Publication No. 6-239786

[Patent Document 5] Japanese Unexamined Patent Application Publication No. 8-92258

### DISCLOSURE OF INVENTION

The present inventors have been studying the changes in reflection spectrum and electric conductivity in EDO-TTF-based complex crystals and have found significant changes in reflection spectrum and electric conductivity in the EDO-TTF-based complex crystals under specific conditions, thus creating an efficient functional element.

In view of the above situation, it is an object of the present invention to provide a method for performing a phase transition of an organic complex in which the phase transition can be performed with a high performance under specific conditions, and a functional element using the same.

In order to achieve the above object, the present invention provides the following:

[1] A method for performing a phase transition of organic complex crystals including a step of changing reflection spectrum and electric conductivity using EDO-TTF-based complex crystals with a single photon per 2,000 to 5,000 molecules.

[2] The method for performing a phase transition of organic complex crystals according to Item [1], wherein the change in reflection spectrum significantly occurs in a wavelength region of 1.5 to 0.8 μm.

[3] The method for performing a phase transition of organic complex crystals according to Item [2], wherein the rate of change in reflection spectrum is 1 to 100 ps.

[4] The method for performing a phase transition of organic complex crystals according to Item [2], wherein the change in reflection spectrum is 100%.

[5] The method for performing a phase transition of organic complex crystals according to any one of Items [1] to [4], wherein a high-speed optical switching is performed at room temperature range and in a terahertz region.

[6] The method for performing a phase transition of organic complex crystals according to Item [1], wherein resistivity and magnetic susceptibility are suddenly changed significantly by performing the phase transition at a temperature of about 280K, thereby sensing the changes in resistance and magnetism.

[7] A functional element including organic complex crystals using the method for performing a phase transition of organic complex crystals according to any one of Items to [6].

[8] The functional element including organic complex crystals according to Item [7], wherein the functional element can operate in a wavelength region of 1.5 to 0.8 μm with a high sensitivity, at a high speed, and at room temperature.

### BRIEF DESCRIPTION OF THE DRAWINGS

FIG. 1 is a schematic view of a functional element including organic complex crystals, which shows an embodiment of the present invention.

FIG. 2 is a schematic view of a system for measuring characteristics of the change in reflectance of the functional element according to the present invention using fixed light.

FIG. 3 is a graph showing measurement results of the change in reflectance of the functional element according to the present invention using fixed light.

FIG. 4 is a graph showing measurement results of the change in reflectance of the functional element according to the present invention using fixed light.

FIG. 5 includes views showing a quasi-one-dimensional organic conductor of ¼-filled (EDO-TTF)₂PF₆.

FIG. 6 shows a chemical structure of EDO-TTF.

FIG. 7 is a graph showing an optical pumping effect of (EDO-TTF)₂PF₆ crystals in a low temperature phase (T=270K)

FIG. 8 is a graph showing a temperature dependence of the change in reflectance when 270K is defined as a standard temperature.

FIG. 9 is a graph showing an optical pumping effect of (EDO-TTF)₂PF₆ crystals in a high temperature phase (T=290K), which shows a comparative example.

FIG. 10 is a graph showing a polarization dependence of pump light in (EDO-TTF)₂PF₆ crystals, which shows a comparative example.

FIG. 11 is a graph showing a dependence of pump light intensity in (EDO-TTF)₂PF₆ crystals.

FIG. 12 includes graphs showing characteristics of a sensor showing a second embodiment of the present invention.

### BEST MODE FOR CARRYING OUT THE INVENTION

The present invention can provide the following advantages:

(1) In EDO-TTF-based complex crystals, the electric conductivity and the reflection spectrum can be changed with a single photon per 2,000 to 5,000 molecules.

(2) The change in reflection spectrum can overlap the frequency region that can be used in optical communication.

(3) The rate of the change in reflection spectrum is high and is 1 to 100 ps.

(4) The rate of the change in reflection spectrum can be achieved at room temperature.

(5) Since EDO-TTF-based complex crystals are an organic substance, the crystals can be readily grown and produced.

(6) In a known method, the change occurs at about liquid nitrogen temperature and the rate of the change is several tens to 100 ps. In addition, the change in reflection spectrum at a wavelength region used in communication is several tens of percent. In contrast, the present invention provides a rate of change of several hundreds of percent and a dramatic high-speed change.

According to the present invention, when 2,000 to 5,000 molecules of an EDO-TTF-based complex crystal is irradiated with a single photon [photons as weak as about 1 to about 10 μJ per square centimeter], the EDO-TTF-based complex undergoes a phase transition to a metal phase (high temperature phase) and an insulator phase (low temperature phase), thereby changing the reflection spectrum and the electric conductivity. Furthermore, the change in reflection spectrum is significantly large in a wavelength region of 1.5 to 0.8 μm, which is important in communication. Also, the change is completed at a rate of 1 to 2 ps and can be performed at room temperature range. Thus, the present inventors have confirmed the possibility of the crystals serving as a high-speed optical switching element in a terahertz region.

In addition, the phase transition due to the temperature occurs at about 280K wherein the resistivity and the magnetic susceptibility are also drastically changed. These phenomena indicate that the EDO-TTF-based complex can function as a sensor.

Embodiments of the present invention will now be described in detail.

### First Embodiment

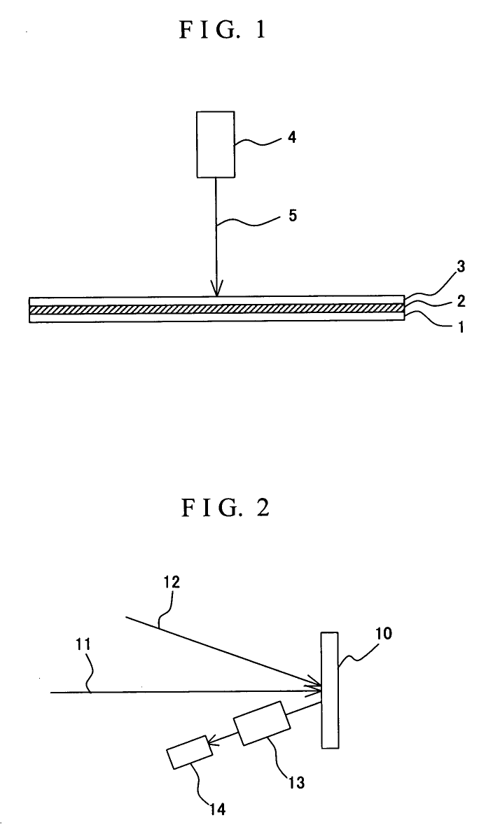

FIG. 1 is a schematic view of a functional element including organic complex crystals, which shows an embodiment of the present invention.

In the figure, reference numeral 1 indicates a substrate, reference numeral 2 indicates organic complex crystals [EDO-TTF-based complex, (EDO-TTF)₂PF₆] provided on the substrate 1, reference numeral 3 indicates a transparent electrode, reference numeral 4 indicates an irradiation source of photons, and reference numeral 5 indicates photons irradiated from the irradiation source 4 of photons.

Firstly, an optical pumping effect in the metal-insulator transition of (EDO-TTF)₂PF₆ will now be described.

FIG. 2 is a schematic view of a system for measuring characteristics of the change in reflectance of the functional element according to the present invention using fixed light.

In the figure, reference numeral 10 indicates a functional element of the present invention, reference numeral 11 indicates pump light, reference numeral 12 indicates probe light, reference numeral 13 indicates a spectroscope, and reference numeral 14 indicates an optical receiver.

Subsequently, the temperature dependence of reflectance in (EDO-TTF)₂PF₆ will now be described.

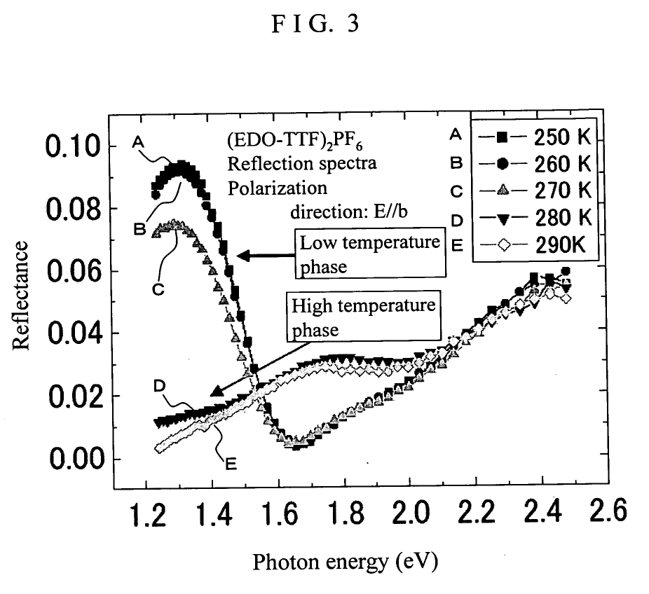

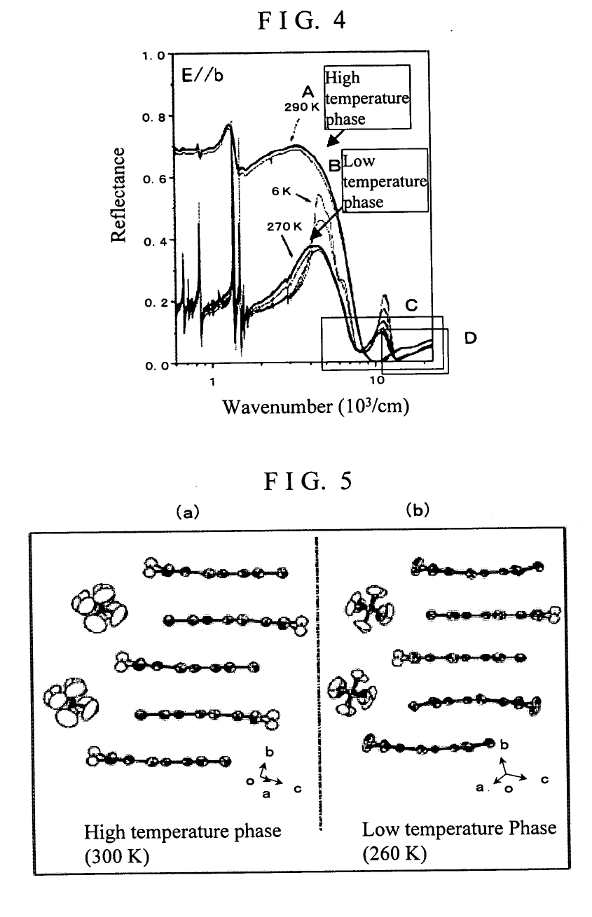

FIG. 3 is a graph showing measurement results of the change in reflectance of the functional element according to the present invention using fixed light. FIG. 3 corresponds to the area indicated by symbol D in FIG. 4, which will be described below.

In the figure, the pump light had an energy of 1.55 eV (800 nm) and the probe light had an energy of 1.38 eV (900 nm). Polarized light (E//b) parallel to the laminated direction of the organic complex crystals was used as both the pump light and the probe light. In other words, light having a wavelength of 800 nm (1.55 eV), which approximately corresponds to the charge-transfer transition energy (1.38 eV) required for F⁺F⁺→F²⁺F⁰, was selected as the pump light.

In the figure, Line A represents the case at 250K, Line B represents the case at 260K, Line C represents the case at 270K, Line D represents the case at 280K, and Line E represents the case at 290K.

As shown in the figure, the reflection spectrum is significantly changed at the threshold of the metal-insulator transition.

FIG. 4 is a graph showing measurement results of the change in reflectance of the functional element according to the present invention using fixed light.

FIG. 4 is a graph showing the characteristics of reflectance measured as a function of the wavenumber by excitation and probe spectroscopy. A time-resolved observation by excitation and probe spectroscopy was performed to observe a photo-induced phase transition from the reflection spectrum. Symbol A indicates a high temperature phase (290K), symbol B indicates a low temperature phase (270K), and symbol C indicates a wavelength region used in communication.

As is apparent from the figure, the reflection spectrum is significantly changed at a threshold of the transition temperature (280K).

Furthermore, when the metal (high temperature) phase and the insulator (low temperature) phase are switched by irradiating light, a significant change in reflectance (high-speed switch for communication) can be provided in a wavelength region of 1.5 to 0.8 μm.

The crystal structure and the features of the (EDO-TTF)₂PF₆ crystals will now be described.

FIG. 5 includes views showing a quasi-one-dimensional organic conductor of ¼-filled (EDO-TTF)₂PF₆. FIG. 5(a) shows the high temperature phase (300K) and FIG. 5(b) shows the low temperature phase (260K).

The quasi-one-dimensional organic conductor of ¼-filled (EDO-TTF)₂PF₆ has the following properties.

(1) The organic conductor has +0.5 valence per donor. (2) The b-axis is directed in the laminated direction. (3) In the low temperature phase in FIG. 5(b), the anion (PF₆) is regularly oriented to form a tetramer. In addition, a flat molecule (F) and a bending molecule (B) are arrayed periodically. In other words, the structure is as follows:
. . . -F-F-B)-(B-F-F-B)-(B- . . .

(4) According to the Raman spectra, the bending molecule (B) has a charge of zero and the flat molecule (F) has a charge of +1.

Substances in which the phase transition by optical pumping can be controlled are promising as a next-generation optical element. In order to achieve the practical application, the optical control must be performed at about room temperature.

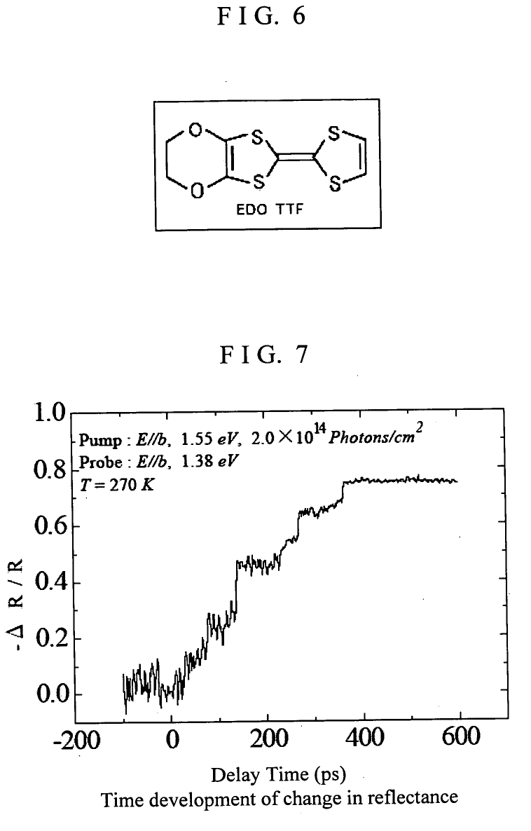

FIG. 6 shows a chemical structure of EDO-TTF.

Whether a photo-induced phase transition is performed or not in this (EDO-TTF)₂PF₆ will now be demonstrated.

Firstly, a metal-insulator transition of (EDO-TTF)₂PF₆ crystals will now be described.

In the low temperature phase,

(1) The crystals are in a [0110] type charge-ordered state.

That is, the crystals become as follows:

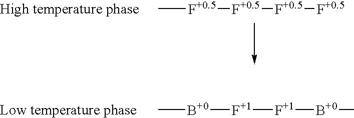

Herein, F represents a flat state and B represents a bending state.

(2) The donor forms a tetramer.

(3) The anion (PF₆) has a regular orientation.

Accordingly, the metal-insulator transition of (EDO-TTF)₂PF₆ crystals is a cooperative phenomenon of a charge-ordering transition, a Peierls transition, and an anion ordering transition.

Subsequently, an optical pumping effect of (EDO-TTF)₂PF₆ crystals in the low temperature phase will now be described.

FIG. 7 is a graph showing the optical pumping effect of (EDO-TTF)₂PF₆ crystals in the low temperature phase. The abscissa indicates a delay time (ps) and the ordinate indicates the reflectance (−ΔR/R). The pump light had an energy of 1.55 eV (800 nm) and the probe light had an energy of 1.38 eV (900 nm). Polarized light (E//b) parallel to the laminated direction of the organic complex crystals was used as both the pump light and the probe light. The temperature T was 270K.

As is apparent from the figure, as the delay time was changed, the reflectance was changed. When the penetration length of the light is 10 μm, 4,000 donors undergo the phase transition per photon at a pump light intensity of 2×10¹⁴ photons/cm².

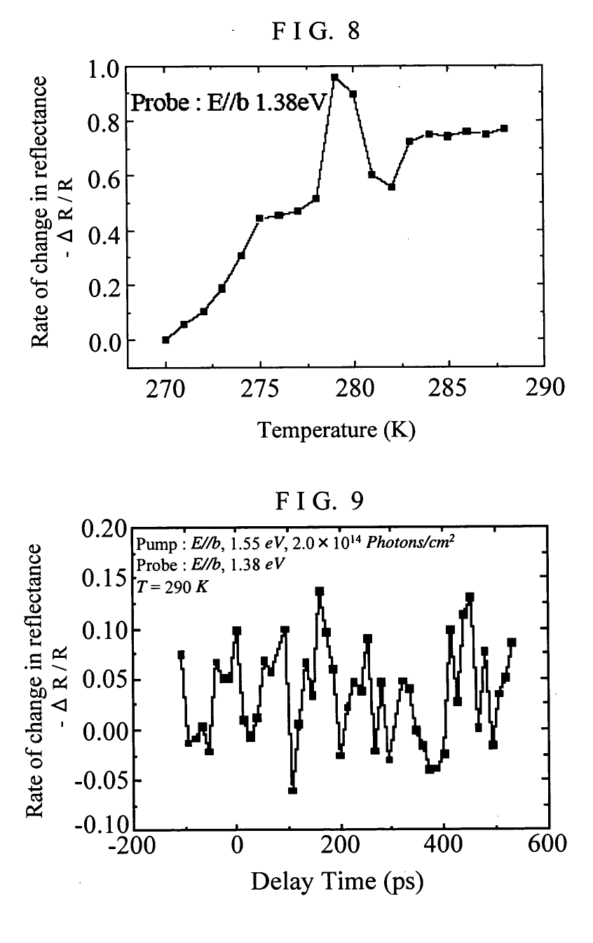

FIG. 8 is a graph showing a temperature dependence of the change in reflectance when 270K is defined as a standard temperature.

In the figure, the probe light was the polarized light (E//b) parallel to the laminated direction of the organic complex crystals and had an energy of 1.38 eV.

According to this result, when the value of reflectance is about zero, the organic complex crystals is in the low temperature phase and when the value of reflectance is about 0.8, the organic complex crystals is in the high temperature phase. The transition temperature is 280K.

The change in reflectance −ΔR/R was calculated as follows:
−ΔR/R=(R_{T}−R_{270K})/R_{270K}

R_{270K}: reflectance at 270K

R_{T}: reflectance at a temperature T during measuring

In the present invention, it was confirmed that even a single photon could change 8,000 to 10,000 molecules of the donor.

In addition, the following can be described.

FIG. 9 is a graph showing an optical pumping effect of (EDO-TTF)₂PF₆ crystals in the high temperature phase (T=290K), which shows a comparative example. The pump light was polarized light (E//b) parallel to the laminated direction of the organic complex crystals and had an energy of 1.55 eV. The pump light intensity was 2.0×10¹⁴ photons/cm². The probe light was also the polarized light (E//b) and had an energy of 1.38 eV. The abscissa indicates a delay time (ps) and the ordinate indicates the reflectance (−ΔR/R).

As is apparent from the figure, even when the delay time was changed, the phase transition from the high temperature phase to the low temperature phase did not occur. [In contrast, under a strong pump light (Line C) in the low temperature phase (T=270K), the photo-excited phase has a long lifetime. Therefore, the subsequent excitation pulse reaches before the phase is returned to the former state.]

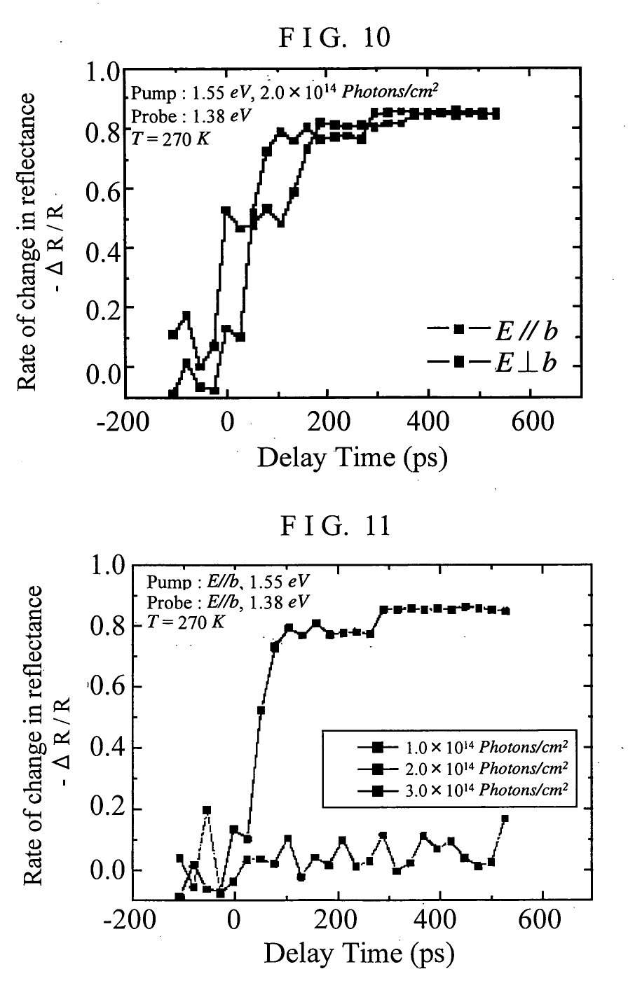

FIG. 10 is a graph showing a polarization dependence of pump light in (EDO-TTF)₂PF₆ crystals, which shows a comparative example. The pump light had an energy of 1.55 eV. The pump light intensity was 2.0×10¹⁴ photons/cm². The probe light had an energy of 1.38 eV. The temperature T was 270K. The abscissa indicates a delay time (ps) and the ordinate indicates the reflectance (−ΔR/R). In the figure, Line A indicates the case where the polarized light is parallel (E//b) to the laminated direction of the organic complex crystals and Line B indicates the case where the polarized light is orthogonal (E™b) to the laminated direction of the organic complex crystals.

As is apparent from the figure, even when the polarization of the pump light was changed, a significant difference was not observed.

FIG. 11 is a graph showing a dependence of pump light intensity in (EDO-TTF)₂PF₆ crystals. The pump light was polarized light (E//b) parallel to the laminated direction of the organic complex crystals and had an energy of 1.55 eV. The pump light intensity was 2.0×10¹⁴ photons/cm². The probe light was also the polarized light (E//b) and had an energy of 1.38 eV. The temperature T was 270K. The abscissa indicates a delay time (ps) and the ordinate indicates the reflectance (−ΔR/R). In the figure, Line A indicates 1.0×10¹⁴ photons/cm², Line B indicates 2.0×10¹⁴ photons/cm², and Line C indicates 3.0×10¹⁴ photons/cm².

As is apparent from the figure, the pump light (Line A) whose intensity is lower than the pump light intensity (Line B) causing the phase transition does not cause the phase transition. Under a strong pump light (Line C) in the low temperature phase (T=270K), the photo-excited phase has a long lifetime. Therefore, the subsequent excitation pulse reaches before the phase is returned to the former state.

### Second Embodiment

Subsequently, a sensor element serving as a functional element and showing a second embodiment of the present invention will now be described.

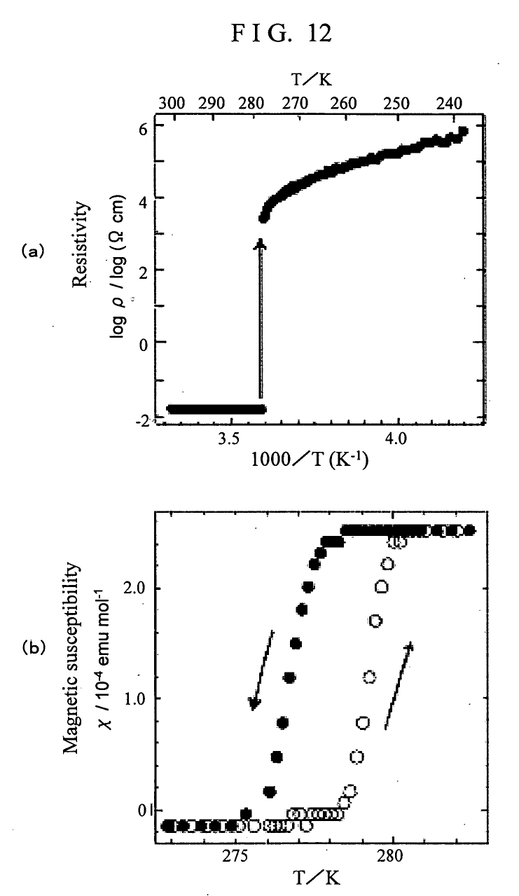

FIG. 12 includes graphs showing characteristics of a sensor showing the second embodiment of the present invention. In FIG. 12(a), the abscissa indicates 1000/T (K⁻¹) and the ordinate indicates resistivity. In FIG. 12(b), the abscissa indicates T/K and the ordinate indicates magnetic susceptibility.

It has been confirmed that (EDO-TTF)₂PF₆ crystals undergo a metal-insulator transition due to the temperature at a threshold of the transition temperature (T_{MI}=280K)

As shown in FIG. 12(a), the resistivity is drastically changed at a threshold of T_{MI}=280K.

As shown in FIG. 12(b), the magnetic susceptibility shows a small hysteresis at the transition point (first-order transition).

Thus, it is apparent that the phase transition due to the temperature occurs at about 280K wherein the resistivity and the magnetic susceptibility are drastically changed. This phenomenon shows that this complex can function as a sensor.

The present invention is not limited to the above embodiments. Various modifications can be made based on the purpose of the present invention, and those modifications are not excluded from the scope of the present invention.

### INDUSTRIAL APPLICABILITY

The functional element using the phase transition of an EDO-TTF-based complex of the present invention is advantageous as an optical switching element in the communication field in the near future where a vast amount of information flies at a high speed because a significant change can be achieved particularly in a wavelength region of 1.5 to 0.8 μm.

1. A method for performing a phase transition of organic complex crystals comprising a step of changing reflection spectrum and electric conductivity using EDO-TTF-based complex crystals with a single photon per 2,000 to 5,000 molecules.

2. The method for performing a phase transition of organic complex crystals according to claim 1, wherein the change in reflection spectrum significantly occurs in a wavelength region of 1.5 to 0.8 μm.

3. The method for performing a phase transition of organic complex crystals according to claim 2, wherein the rate of change in reflection spectrum is 1 to 100 ps.

4. The method for performing a phase transition of organic complex crystals according to claim 2, wherein the change in reflection spectrum is 100%.

5. The method for performing a phase transition of organic complex crystals according to any one of claims 1 to 4, wherein a high-speed optical switching is performed at room temperature range and in a terahertz region.

6. The method for performing a phase transition of organic complex crystals according to claim 1, wherein resistivity and magnetic susceptibility are suddenly changed significantly by performing the phase transition at a temperature of about 280K, thereby sensing the changes in resistance and magnetism.

7. A functional element comprising organic complex crystals using the method for performing a phase transition of organic complex crystals according to any one of claims 1 to 6.

8. The functional element comprising organic complex crystals according to claim 7, wherein the functional element can operate in a wavelength region of 1.5 to 0.8 μm with a high sensitivity, at a high speed, and at room temperature.
